(19) United States
(12) Patent Application Publication
(10) Pub. No.: US 2019/0339346 A1
(43) Pub. Date: Nov. 7, 2019

(54) Magnetic Coil With Incomplete Geometric Configuration

(71) Applicants: Tesoro Imaging, S.L., Alicante (ES); Consejo Superior de Investigaciones Cientificas, Madrid (ES)

(72) Inventors: Daniel Grau Ruiz, Alicante (ES); Juan Pablo Rigla Pérez, Alicante (ES); Elena Díaz Caballero, Alicante (ES); José María Benlloch Baviera, Valencia (ES)

(21) Appl. No.: 16/126,233

(22) Filed: Sep. 10, 2018

(30) Foreign Application Priority Data
May 7, 2018 (ES) P201830448

(51) Int. Cl. G01R 33/385

(52) U.S. Cl. CPC G01R 33/3858

(57) ABSTRACT

The main object of the present invention relates to the design of magnetic coils. In particular, it is aimed at improving the design of magnetic coils to reach high and very fast magnetic fields. The present invention improves the design of one of the main components, gradient coils system, of imaging equipment based on the technique of magnetic resonance imaging (MRI).

In this invention, a magnetic coil with incomplete geometrical configuration is provided. The magnetic coil is characterized in that at least one of its spirals is incomplete. The manufacturing method is based on combinatorial filling.

In addition, the magnetic coil presented in this invention can achieve intense and fast magnetic gradients.

This application claims priority to Spanish patent application no. P201830448, filed May 7, 2018, the entire contents of which is incorporated herein by reference.

### FIELD OF THE INVENTION

The main object of the present invention belongs to the field of manufacture of magnetic coils. In particular, it is aimed at improving the design of magnetic coils to reach high and very fast magnetic fields. The method presented in this invention is applied to improve the design of one of the main components, gradient coils system, of imaging equipment based on the technique of magnetic resonance (MR).

### BACKGROUND OF THE INVENTION

Magnetic resonance (MR) is an imaging modality based on the phenomenon of nuclear magnetic resonance (NMR). Different from other more used imaging techniques, such as X-ray systems, it does not use ionizing radiation to generate the images but uses magnetic fields and radiofrequency (RF). The main components of the MRI equipment are a principal magnetic system (B₀), a RF system and a magnetic gradients system. The magnetic gradient system allows the spatial coding of the RF signal necessary to perform the reconstruction of the images, Said coding is achieved by the addition of the gradient fields, linear and orthogonal to each other, on the magnetic field B₀, thus obtaining a coding in phase and frequency different for each voxel of the field of vision. The RF coil receives the signal emitted by the hydrogen nucleus of the water molecules and, through the use of the Fourier Transform (TF), a group of images that provide structural and functional information of the body under study is obtained.

In recent years, there has been an increase in the interest in obtaining structural images with a high contrast (high SNR—signal to noise ratio—) and with a high spatial resolution (<100 μm) by using MRI system, both in the medical and in the research field. To perform these objectives, several alternatives have been proposed such as the use of high magnetic fields or the combination of two magnetic fields, a static one (evolution field) and another one pulsed (pre-polarization field) together with the use of intense and fast magnetic gradients (rise time ≤10 microseconds).

From the technological point of view, the generation of intense magnetic gradients is a great challenge. This is because of high intensity power supplies (I>200 A) are required to generate intense magnetic gradients. The use of high intensities is associated with the need to implement an efficient cooling system to avoid overheating of the magnetic coils used to generate said magnetic gradient fields. To avoid overheating, as well as to achieve fast magnetic gradients, an optimization of the geometry of these coils is required in order to reduce both their resistance and inductance, as well as special manufacturing methods.

Application U.S. Pat. No. 3,515,979A describes a magnetic field control device produced by a plurality of electrical circuits and where the shape of the windings used is determined by mathematical expressions given for the harmonics, respectively. However, in the present invention a magnetic coil is described such as that the gradient magnetic field is generated from a single electric circuit, what facilitates the generation of a magnetic gradient without the need of a control device that controls the plurality of circuits.

Application US006054854 A describes the current directions in the coils, although it does not describe the geometry of the windings, something that the present invention does.

Application U.S. Pat. No. 5,561,371 A describes a system of magnetic gradients composed of three coils. The forms used are half turns with an elliptical shape making use of two different radius. The geometry used in U.S. Pat. No. 5,561,371 A describes a system of self-shielded gradients, having the disadvantage that the coils are always shielded. Shielding, however, is not always necessary due to geometrical or magnetic aspects. The present invention uses windings that form full turns, allowing the generation of windings to obtain the gradient coils and/or the shield coils.

Application U.S. Pat. No. 4,646,024 A describes the coil using 4 windings. However, the present invention designs coils using 4 n windings in the transverse gradient coils and 2·n windings in the longitudinal gradient coils, where n is a natural number.

The aim of the present invention is a magnetic coil with an incomplete geometrical configuration, as well as the manufacture of said magnetic coil with incomplete geometrical configuration used in the MRI system, making use of a new manufacturing method, based on combinatorial filling. Until now, said method has not been used in the design of gradient coils.

The method of this invention will be used to manufacture magnetic coils for the MRI system in order to reach intense and fast magnetic gradients making use of different configurations, such as total or partial fillings, and incorporating an efficient cooling system, in case that it was necessary to include it.

### DESCRIPTION OF THE INVENTION

In this specification the term “coil” or “magnetic coil” has the usual meaning, that is, is a rolled up conductive material, which can be forming one or more windings, and which stores energy in the form of a magnetic field.

In this report the term “incomplete” has the usual meaning, that is, it is not complete. The concept “incomplete” in this invention is applied to the concept of magnetic coil with an incomplete geometric configuration, that is, that along the winding there is at least one jump step between turns of at least one spiral of the coil.

The expression “jump step” refers to a magnetic coil where there is a gap within one turn of the coil or within one of the spirals forming the coil.

The present invention refers to a magnetic coil with an incomplete geometrical configuration. The magnetic coil is characterized because at least one of its spiral is incomplete and has a maximum resistance of 5Ω, or a maximum inductance of 1000 mH, or has a maximum resistance of 5Ω and a maximum inductance of 1000 mH.

According to particular embodiments, a magnetic coil with resistance values R=0.524Ω and an inductance L=11.1 μH is presented.

The magnetic coil is made up of an electrical conductor that is selected from among a cable, a track and a tube. In electronics, track is understood to be those paths of conductive material laminated and, generally, arranged on a non-conductive base, substrate. A cable is a conductor or group of them generally covered by an insulating or protective material. A tube is a hollow piece generally open at both ends; this geometry allows, in addition to transmitting an electric current through the conductor located in its interior t, transporting a refrigerant fluid through its hollow inside.

According to particular embodiments, the electrical conductor that constitutes the magnetic coil adopts the form of spirals which are distributed in rows and columns.

The coil, as well as the form acquired by it, is the result of carrying out a manufacturing method consisting of 2 steps. The first step consists of determining the position and number of turns of the electrical conductor through a process of combinatorial optimization. The second step comprises placing the electric conductor in the appropriate positions to obtain the geometry obtained in the first step.

The first step consists of several sub-stages:
Different initial configurations are designed by filling the substrate area with different thicknesses of the conductive material and different separations between the adjacent turns.
The magnetic field produced by each of the turns defined in each of the initial configurations is calculated separately.
The magnetic field generated by each combination of turns is calculated using combinatorics.
The optimal configuration of turns is determined for the manufacture of the coil.

In this specification the term “thickness” has the usual meaning, that is, the thickness or width of a solid.

The different initial configurations are obtained taking into account geometricai parameters such as:
Maximum surface where the magnetic coil will be built.
Minimum thickness of electrical conductor (tₘᵢₙ).
Minimum separation between adjacent turns (sₘᵢₙ).
Number and initial distribution of spirals.

Once the geometrical parameters have been introduced, the entire surface begins to be filled in, and a complete filling is carried out. The spirals of the coil are located in different positions, as previously mentioned.

Different initial configurations are made by filling the surface using different thicknesses of electrical conductor and separations between adjacent turns. The number of these initial configurations corresponds to:

N_{b}=Nₜ·Nₛ (1)

where
N_{b}=Number of coils
Nₜ=Number of thicknesses of electrical conductor
Nₛ=Number of separations between adjacent turns

The number of thicknesses of electrical conductor and the number of separations between adjacent turns is defined by:

$$\begin{matrix}{N}_{t} = \frac{{t}_{max} - {t}_{min}}{Δ t} + 1 & ( 2 ) \\ {N}_{s} = \frac{{s}_{max} - {s}_{min}}{Δ s} + 1 & ( 3 )\end{matrix}$$

The path separates in as many turns as each spiral contains and it is calculated, separately, the magnetic field produced by each of the turns using the Biot-Savart law as a function of the current intensity flowing through the electrical conductor. By using combinatorics the magnetic field generated by each combination of turns is calculated.

The number of possible combinations (N_{comb}) for each initial configuration with “I” spirals and with a thickness of electrical conductor, t, and a separation between adjacent turns, s, is:

$${N}_{comb} = {[ {\sum }_{p = 1}^{n} ( \begin{matrix}n \\ p\end{matrix} ) ]}^{l} \qquad ( 4 )$$

where n is the total number of turns in each initial configuration and p is the number of turns used in each of the possible combinations, and where:

$$( \begin{matrix}n \\ p\end{matrix} ) = \frac{n !}{p ! ( n - p ) !} \qquad ( 5 )$$

Knowing that the method performs different initial configurations according to the thickness of the electrical conductor and the separation between adjacent turns, the total number of combinations will be:

Ncombₜₒₜₐₗ=Σᵢ₌₁^{Nb}N_{comb}(i) (6)

The manufacturing method obtains values of certain physical parameters for each of the possible combinations, such as:
Coil resistance (Ω).
Coil inductance (μH).
Gradient intensity α(mT/m/A) obtained.
Current intensity I(A) flowing through the coil.
Final gradient G (T/m) obtained, knowing that: G(T/T/m)=∝(mT/m/A)×I(A).
Magnetic field generated by the coil.
Linearity along the X and Y axis in the region of interest, for X and Y gradients, respectively.
Linearity along the Z axis in the region of interest for Z gradients.
Homogeneity in the XY plane in the region of interest for Z gradients.

The user selects one or more of the parameters as a target parameter so that the optimal combination for the manufacturing of the coil is determined. The turns of the coil that are not selected as the optimal combination are eliminated while the selected ones are joined together to make a single coil.

The coil can be made on a substrate of dielectric material or without said substrate.

The coil provided by this invention is used in the construction of magnetic devices, open or closed, responsible for generating magnetic field.

The coil provided is also used for the construction of the gradient coils of the MRI system responsible for generating the magnetic gradient in the region of interest along each of the space axes, as well as for the construction of shielding coils responsible for generating a magnetic field such that minimizes the magnetic field generated by the gradient coils in the main magnetic system.

The present invention has also as an object a method of manufacturing magnetic devices responsible for generating magnetic fields comprising:
disposing one or more magnetic coils wherein at least one of the spirals has an incomplete geometrical configuration, so that along the winding there is at least one jump step between turns of at least said coil spiral, and said coil has:
   a maximum resistance of 5Ω, or
   a maximum inductance of 1000 mH, or
   a maximum resistance of 5Ω and a maximum inductance of 1000 mH, and
generating a magnetic field.

Said magnetic devices can be of open or closed magnetic devices.

According to particular embodiments the method refers to the construction of the gradient coils of a MRI system responsible for generating the magnetic gradient in the region of interest along each of the axes of the space.

According to additional particular embodiments the method refers to the construction of the shielding coils of a MRI system responsible for generating a magnetic field such that minimizes the magnetic field generated by the gradient coils in a main magnetic system.

### BRIEF DESCRIPTION OF THE FIGURES

In order to help a better understanding of the characteristics of the invention, a set of drawings is included as an integral part of said description, where, for illustrative purposes, the following is represented:

FIG. 1 shows the initial coil used to generate a magnetic gradient X or Y, once the filling is completed with a thickness of electrical conductor, t=1.1 mm.

FIG. 2 shows the initial coil used to generate a magnetic gradient X or Y, once the filling is completed with a thickness of electrical conductor, t=1.6 mm.

FIG. 3 shows the initial coil used to generate a magnetic gradient X or Y, once the filling is completed with a thickness of electrical conductor, t=2.1 mm.

FIG. 4 shows the turns separated from each other, for the geometry shown in FIG. 1.

FIG. 5 shows the turns separated from each other, for the geometry shown in FIG. 2.

FIG. 6 shows the turns separated from each other, for the geometry shown in FIG. 3.

FIG. 7 shows the selected optimum coil (t=2.1 mm), used to generate a magnetic gradient X or Y. The figure shows the optimal turns selected and not selected by continuous and discontinuous lines, respectively.

FIG. 8 shows the final optimum coil (t=2.1 mm), with the turns that are part of the coil final design, used to generate a magnetic gradient X or Y.

FIG. 9 shows the initial coil, used to generate a magnetic gradient Z, once the filling is completed with a thickness of electrical conductor, t=2.1 mm.

FIG. 10 shows the turns separated from each other, for the geometry shown in FIG. 9.

FIG. 11 shows the selected optimum coil, used to generate a magnetic gradient Z. The figure shows the optimal turns selected and not selected by continuous and discontinuous lines, respectively.

FIG. 12 shows the final optimum coil, with the turns that are part of the final design of the coil, used to generate a magnetic gradient Z.

### DESCRIPTION OF THE PARTICULAR EMBODIMENTS

Some examples of particular embodiments relating to the incomplete magnetic coil are described below.

### Example of Particular Embodiment 1

A magnetic coil of a resistance of R=0.205 Ω and an inductance of L=1.2 pH and formed by 2 spirals with 3 turns each, is made on a dielectric substrate, FR4, and installed in a MRI system with the object of generating the magnetic gradient in the region of interest. Said coil is used to generate the magnetic gradient X or Y. It is to be noted that by rotating 90° a magnetic coil that generates a gradient on the X axis, it becomes a magnetic coil that generates a gradient on the Y axis.

The geometric parameters taken into account for the obtaining of the initial configurations are the following ones:
Maximum surface where the magnetic coil is to be built: 95 mm×95 mm
Minimum thickness of electrical conductor: 1.1 mm
Minimum separation between adjacent turns: 0.3 mm
Number and initial distribution of spirals: 4 spirals in total, distributed in 4 rows y 1 column.

In this particular embodiment, initial configurations are made for 3 additional thicknesses of electrical conductor: 1.1 mm, 1.6 mm y 2.1 mm.

The manufacturing method carries out a filling of the available surface.

The number of initial configurations is given by the number of track thicknesses (N₁) and the number of separations between tracks (Nₛ) defined by equations (2) and (3), respectively. Since the thickness of electrical conductor is 1.1 mm, 1.6 mm and 2.1 mm, and the spacing between adjacent turns is kept constant at 0.3 mm, it is obtained from (1) that the number of initial coils, N_{b}, is:

N_{b}=Nₜ*Nₛ=3*1=3 initial coils

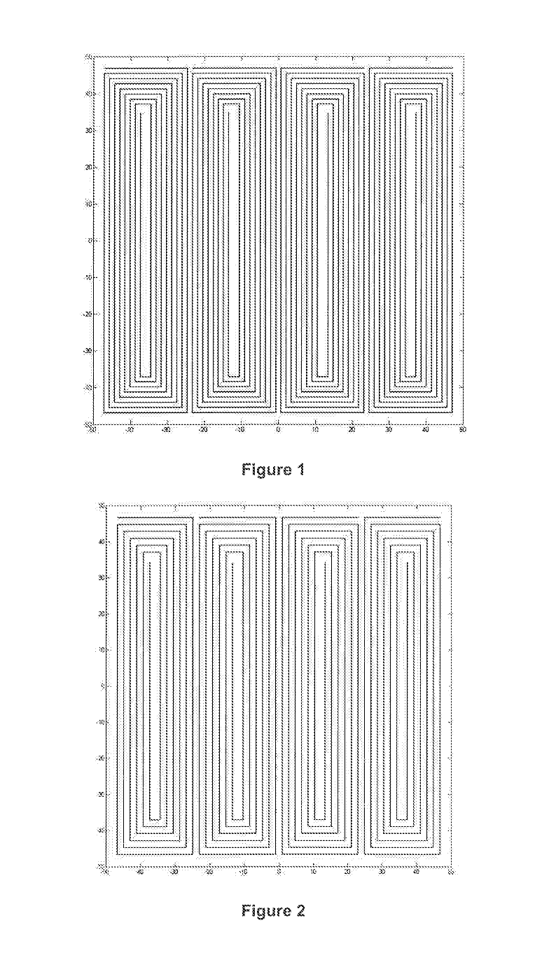

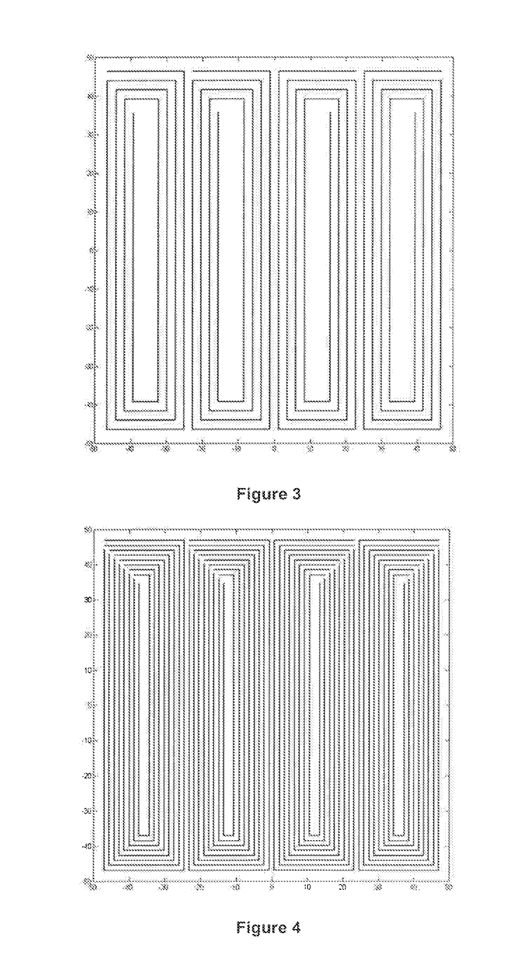

FIGS. 1, 2 and 3 show the initial configurations obtained after the filling in for each one of the options, corresponding to a track thickness (t) of 1.1 mm, 1.6 mm and 2.1 mm, respectively. The three initial configurations show 4 initial spirals, a separation between adjacent turns of 0.3 mm and a maximum area of 95 mm×95 mm. The number of turns per spiral are 8, 6 and 4 for the thicknesses t=1.1 mm, t=1.6 mm y t=2.1 mm, respectively.

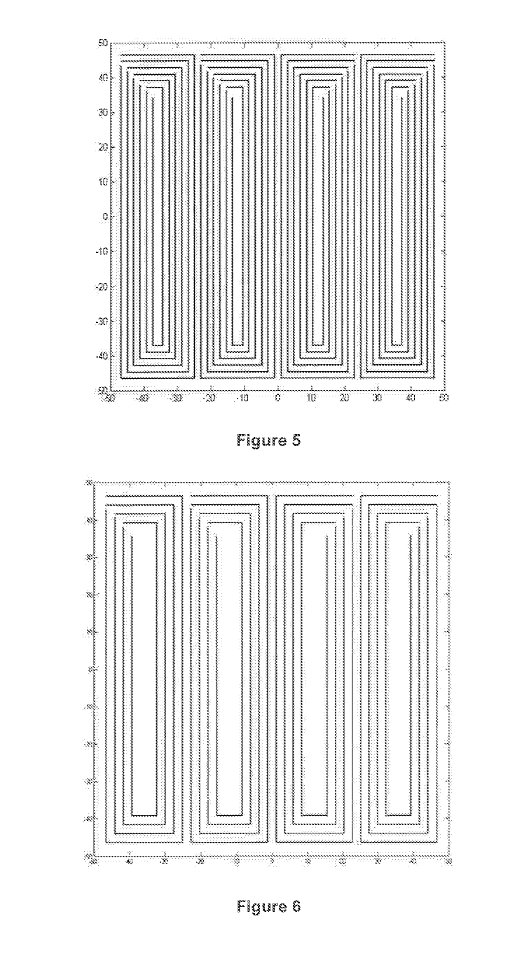

The magnetic field generated by each of the turns using the Biot-Savart law as a function of the intensity of current flowing through the electrical conductor is calculated separately. FIGS. 4, 5 and 6 show the initial coils with the separate turns.

The number of possible combinations (N_{comb}) for each of the initial configurations is given by the expressions (4) y (5):

Case t=1.1 mm;
Knowing that n=8 and I=4, N_{comb}=(255)₄ combinations.

Case t=1.6 mm:
Knowing that n=6 and I=4, N_{comb}=(63)⁴ combinations.

Case t=2.1 mm:
Knowing that n=4, and I=4, N_{comb}=(15)⁴ combinations.

The total number of possible combinations is, as expression (6) indicates:

Ncombₜₒₜₐₗ=(255)⁴+(63)⁴+(15)⁴

The manufacturing method calculates the magnetic field generated by each of the possible combinations.

In this particular embodiment, the output parameter selected as the target parameter is the maximum gradient G (T/m) generated. The electric power (P=V*I=I²*R) supplied in each case is constant, so the intensity supplied to each of the possible combinations is determined by the resistance of each of said combinations.

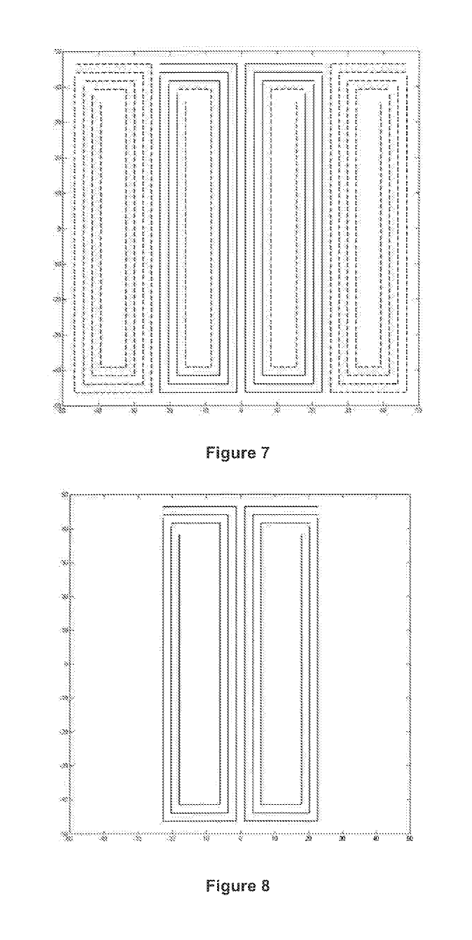

FIG. 7 shows the optimal geometry of the coil. This corresponds to the case of thickness of t=2.1 mm. The turns shown with discontinuous lines are those turns that are not selected to be part of the final optimum coil. In said geometry all the turns of the spirals at the ends, and also the innermost turn of the central spirals, have been eliminated.

FIG. 8 shows the design of the final coil that is subsequently manufactured on a FR4 substrate.

### Example of Particular Embodiment 2

A magnetic coil of a resistance of R=0.524 Ω and an inductance of L=11.1 pH and formed by 1 spiral with 14 turns each one, is manufactured on a dielectric substrate, FR4, and installed in a RM equipment [12] in order to generate the magnetic gradient in the region of interest. Said coil is used to generate the magnetic gradient Z.

The geometric parameters taken into account for the obtaining of the initial configurations are the following ones:
Maximum surface where the magnetic coil is to be built: 95 mm×95 mm
Minimum thickness of electrical conductor: 2.1 mm
Minimum separation between adjacent turns: 0.3 mm
Number and initial distribution of spirals: 1 spiral in total, distributed in 1 row and 1 column.

The manufacturing method carries out a filling of the available surface.

The number of initial configurations is given by the number of track thicknesses (Nₜ) and the number of separations between tracks (Nₛ) defined by equations (2) and (3), respectively. Since the thickness of electrical conductor is 2.1 mm and the spacing between adjacent turns is 0.3 mm, it is obtained from (1) that the number of initial coils, Nb, is:

N_{b}=Nₜ*Nₛ=1*1=1 initial coil.

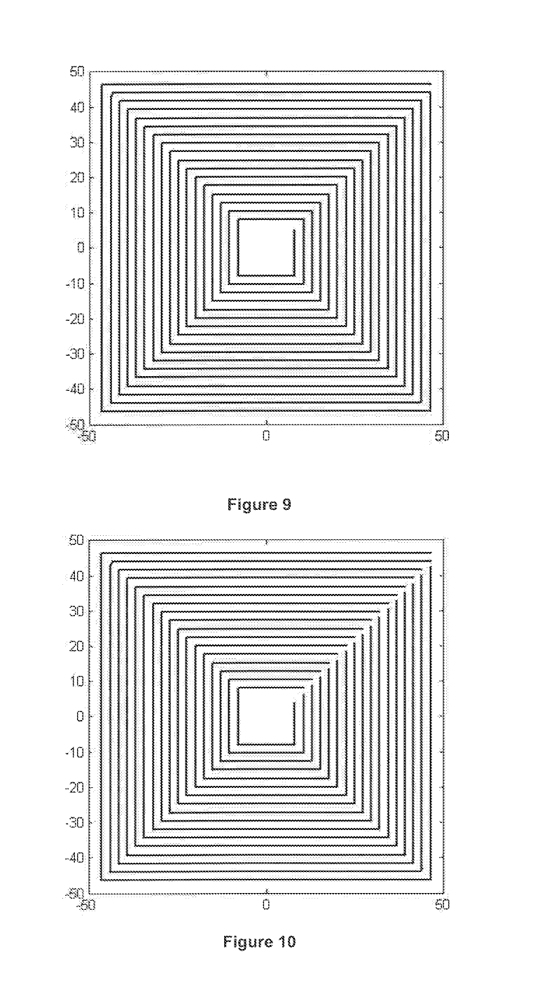

FIG. 9 shows the initial configurations obtained after carrying out the filling. The initial configuration shows 1 spiral, a separation between adjacent turns of 0.3 mm and an area of 95 mm×95 mm. The number of initial turns is 17.

The magnetic field generated by each of the turns using the Biot-Savart law as a function of the intensity of current flowing through the electrical conductor is calculated separately. FIG. 10 shows the initial coils with the separate turns.

The number of possible combinations (N_{comb}) for each of the initial configurations is given by the expressions (4) y (5):
Knowing that n=17 and I=1, N_{comb}=(131071)¹ combinations.

The total number of possible combinations is given by expression (6), and since N_{b}=1:

Ncombₜₒₜₐₗ=(131071)¹=131071 combinations

The manufacturing method calculates the magnetic field generated by each of the possible combinations.

In this particular embodiment, the output parameter selected as the target parameter is the maximum gradient G (T/m) generated. The electric power (P=V*I=I²*R) supplied in each case is constant, so the intensity supplied to each of the possible combinations is determined by the resistance of each of said combinations.

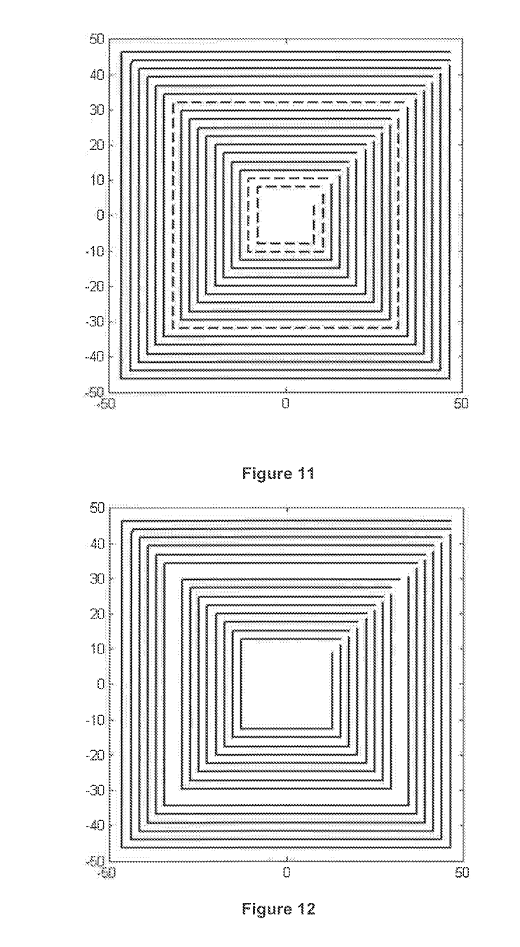

FIG. 11 shows the optimal geometry of the coil. The turns shown with discontinuous lines are those turns that are not selected to be part of the final optimum coil, Turns 7, 16 and 17 have been eliminated.

FIG. 12 shows the design of the final coil that is subsequently manufactured on a FR4 substrate.

FIG. 12 shows the concept of ‘incomplete geometrical configuration’ in the jump from turn 6 to 8, since turn 7 is eliminated and is not used to wind the final coil.

1. A magnetic coil comprising one or more spirals, wherein at least one of the spirals has an incomplete geometrical configuration, so that along the winding there is at least one jump step between turns of at least said coil spiral, and said coil has:
a maximum resistance of 5Ω, or
a maximum inductance of 1000 mH, or
a maximum resistance of 5Ω and a maximum inductance of 1000 mH.

2. The magnetic coil according to claim 1, comprising spirals distributed in rows and columns.

3. The magnetic coil according to claim 1, comprising an electrical conductor selected from a cable, a track and a tube.

4. The magnetic coil according to claim 3, comprising spirals distributed in rows and columns.

5. A method of manufacturing a magnetic coil wherein at least one of the spirals has an incomplete geometrical configuration, so that along the winding there is at least one jump step between turns of at least said coil spiral, and said coil has:
a maximum resistance of 5Ω, or
a maximum inductance of 1000 mH, or
a maximum resistance of 5Ω and a maximum inductance of 1000 mH,
said method comprising the steps:
a. determining the position and number of turns of the electrical conductor through a combinatorial optimization process
b. placing an electrical conductor to obtain the geometry obtained in the previous step.

6. The method of manufacturing coils according to claim 5, wherein the first step comprises:
a. performing different initial configurations by filling the substrate area with different thicknesses of conductive material and different separations between the adjacent turns
b. calculating, separately, the magnetic field produced by each of the turns defined in each of the initial configurations
c. calculating the magnetic field generated by each combination of turns making use of combinatorics
d. determining the optimal configuration of turns for the manufacture of the coil.

7. A method of manufacturing a magnetic device responsible for generating magnetic fields comprising:
disposing one or more magnetic coils comprising one or more spirals, wherein at least one of the spirals has an incomplete geometrical configuration, so that along the winding there is at least one jump step between turns of at least said coil spiral, and said coil has:
a maximum resistance of 5Ω, or
a maximum inductance of 1000 mH, or
a maximum resistance of 5 Ω and a maximum inductance of 1000 mH, and
generating a magnetic field.

8. The method according to claim 7 wherein the magnetic device is selected from open and closed magnetic devices.

9. The method according to claim 7 wherein the coil is a gradient coil of a RM equipment responsible for generating a magnetic gradient in the region of interest along each of the axes of the space.

10. The method according to claim 7 that comprises the manufacturing of shielding coils of a MRI system responsible for generating a magnetic field such that minimizes the magnetic field generated by the gradient coils in a main magnetic system.
